(19) United States
(12) Patent Application Publication
(10) Pub. No.: US 2012/0171800 A1
(43) Pub. Date: Jul. 5, 2012

(54) METHOD OF SEALING AN ELECTRONIC DEVICE

(75) Inventors: Stephen Yau Sang Cheng, Hong Kong (HK); Chui-Ling Yip, Hong Kong (HK); Chung-Pui Chan, Hong Kong (HK)

(73) Assignee: DU PONT APOLLO Ltd., Pak Shek Kok (HK)

(21) Appl. No.: 12/982,249

(22) Filed: Dec. 30, 2010

(51) Int. Cl. H01L 31/18; H01J 9/26

(52) U.S. Cl. 438/64; 445/25; 257/E31.11

(57) ABSTRACT

A method of sealing an electronic device is disclosed, comprising providing an assembly comprising first and second substrates in an opposed relationship, and an electronic device positioned between the first and second substrates; positioning a glass rod against or on the edge of the first and/or second substrate; and heating and softening the glass rod to form a hermetic seal between the first and second substrates and form a hermetically sealed electronic device.

### BACKGROUND OF THE INVENTION

1. Field of the Invention

The present invention relates generally to a method of sealing an electronic device, and particularly to a method of sealing a photovoltaic cell.

2. Description of the Related Art

Nowadays, electronic devices, such as organic light emitting diode (OLED) displays, surface emission displays (SEDs), field emission displays (FEDs), liquid crystal displays (LCDs), and photovoltaic cells, have been the subject of a considerable amount of research in recent years. In particular, photovoltaic cells hold great promises because of their potential use in providing cleaner and renewable energy. However, like certain electronic devices, in order to be functionally efficient for their intended purposes, photovoltaic cells require protection from the environment and are usually packaged tightly between glass substrates.

Traditionally, bonding of glass substrates is usually achieved by lamination process. Ethyl vinyl acetate (EVA), polyvinyl butyral (PVB), other encapsulants, or adhesives are applied between the front and back substrates. In order to combine different substrates and encapsulants together, fine tuning of recipes are needed and the lamination process time is long. Moreover, adhesives, such as epoxy, do not form seals between the glass substrates with sufficient hermiticity to yield long electronic device lifetime.

One promising approach to extending the life of electronic devices is to employ a glass frit as the sealing material between the glass substrates. By using a glass frit as the sealing material between the glass substrates of an assembly comprising an electronic device, a hermetic package can be produced. Nevertheless, to ensure proper sealing, the glass frit must have sufficient contact with the substrates and dispensed on the substrate in a pattern resembling to a loop. Moreover, a force needs to be applied to at least one of the substrates during the sealing process to provide good contact between the glass frit and the substrates. For example, in order to apply a clean and non-contaminating force to the substrate, WO 2009/099589 A1 (corresponding to US 2009/0203283) employs an electric current flowing through a plurality of electromagnets to cause a ferrous plate to apply a force against an electronic assembly.

### BRIEF SUMMARY OF THE INVENTION

In accordance with one or more embodiments of the invention, a method of sealing an electronic device is disclosed, comprising: providing an assembly comprising first and second substrates in an opposed relationship, and an electronic device positioned between the first and second substrates; positioning a glass rod against or on the edge of the first and/or second substrate; and heating and softening the glass rod to form a hermetic seal between the first and second substrates and form a hermetically sealed electronic device.

The step of heating and softening may be performed at a temperature of at least about 500° C., preferably at a temperature of from about 500° C. to 600° C.

The assembly may further include one or more spacers or pegs positioned on the electronic device to separate the first and second substrates.

In accordance with one or more embodiments of the invention, a hermetically sealed electronic device formed by the above method is disclosed.

In accordance with one embodiment of the invention, the electronic device is a photovoltaic cell.

It should be noted that although the following discussion is directed to the sealing of a photovoltaic cell, the present invention may be employed in other applications where the formation of a hermetic seal between two suitable substrates is required, and in particular where the sealing of glass substrates with glass rod to form a hermetically sealed glass package. For example, to name a few, the present invention may be used in the sealing of organic light emitting diode (OLED) displays, surface emission displays (SEDs), field emission displays (FEDs), and liquid crystal displays (LCDs).

### BRIEF DESCRIPTION OF THE DRAWINGS

FIG. 1 is a cross sectional view of a sealed electronic device in accordance with an embodiment of the present invention.

FIG. 2 is a cross sectional view of a sealed electronic device in accordance with another embodiment of the present invention.

Like reference numerals refer to corresponding parts throughout the several drawings. Dimensions are not drawn to scale.

### DETAILED DESCRIPTION OF THE INVENTION

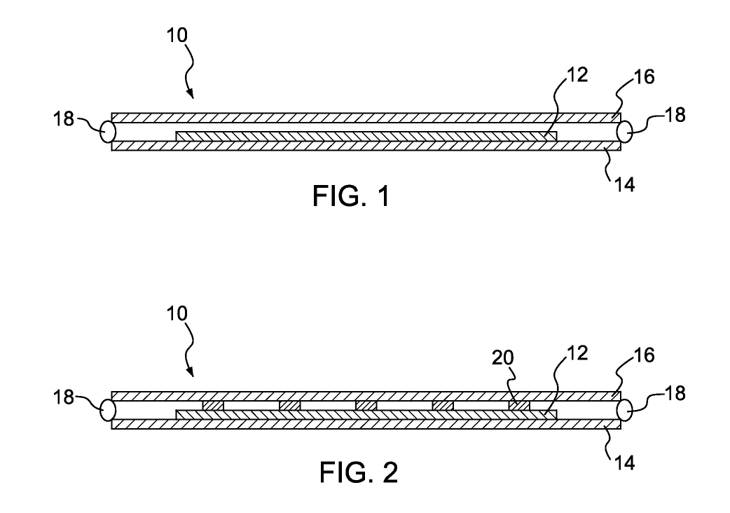

Referring to FIG. 1, a hermetically sealed electronic device 10 comprises at least one photovoltaic cell 12 between two substantially planar substrates 14 and 16, a hermetic seal 18 being formed against the edges of the substrates 14 and 16. Either or both of the substrates may be glass sheets or glass substrates. In one embodiment, one of the substrates may be formed from metals, alloys, ceramics, quartz, and/or polymers. Photovoltaic cell 12 is positioned on the substrate 14 and comprises one or more semiconductor layers and electrode layers (e.g. front contact and back contact), not individually shown in FIG. 1. Lead wires (not shown) may be provided in contact with the electrode layers to pass the current and derive an output from the photovoltaic cell. For example, the hermetically sealed electronic device 10 may include circuitry, also disposed on the substrate 14, to deliver the current.

To provide certain voltage, a number of photovoltaic cells may be disposed within the boundaries of the two substrates 14 and 16 and electrically connected to each other, to form a photovoltaic module.

In one embodiment of the present invention, one or more photovoltaic cells are disposed on the first substrate 14. A closed wall is formed against the edges of the substrates 14 and 16 with glass rods 18 to seal the photovoltaic cell 12. In one embodiment, the glass rod 18 is positioned on edges of one of the substrates as a wall in closed pattern resembling a loop or frame that, after which the other substrate is positioned opposite the first substrate such that the glass rod is positioned between the first and second substrates, and the one or more photovoltaic cells are located within the encircling glass wall. In another embodiment, the first and second substrates are brought together and then the glass rod 18 is positioned against both edges of the substrates as a wall in closed pattern resembling a loop or frame between the first and second substrates.

In one embodiment, the glass rod is heated until the glass rod softens prior to it is brought to in contact with the edges of the substrates, and then cools, to form hermetic seal between and connect the first and second substrates. In another embodiment, the glass rod is first brought to in contact with the edges of the substrates, and heated until the glass rod softens, and then cools, to form hermetic seal between and connect the first and second substrates. In one embodiment, the hermetic seal between the first and second substrates formed by heating the glass rod may have a curved edge. In other words, the hermetically sealed electronic device according to the invention may have a curved edge.

The heating of the glass rod can be performed, for example, by employing an irradiation source such as a laser, a broadband source such as an infrared lamp, an ultrasonic device, or a heating device or mechanism known in the art, or through heating at least one of the first and second substrates.

The heating temperature of the glass rod may be at least about 500° C., preferably at a range from about 500° C. to 600° C. The glass rod can be borosilicate glass (Pyrex®) or quartz glass.

In a laser sealing procedure, the glass rod and the laser may be selected such that the glass rod is highly absorbing at the wavelength, or range of wavelengths of light emitted by laser. For example, the glass rod composition may be materials such that the glass rod is highly absorbing in the infrared wavelength region, in which case a laser should be chosen that emits a light in the infrared wavelength region. On the other hand, it is desirable that the first and/or second substrates 14 and 16, through which the emitted laser light passes on its way to the glass rod are substantially transparent to the laser light.

Prior to the glass rod is positioned on or against the edges of the substrate, the moisture within the assembly may be removed by purging nitrogen gas to ensure the hermetic condition of the sealing process.

It should be understood that the present invention is not limited to the manufacture of photovoltaic cells, but may be satisfactorily used on a wide variety of devices that may benefit from a method capable of forming a hermetic seal between two substrates. Embodiments of the present invention may be used to seal other electronic devices.

In some embodiments, a mask may be used to protect sensitive areas of the electronic device from overheating. For example, the use of a mask may be desirable if a broadband source such as an infrared lamp is the irradiating source. The mask blocks selected regions of the assembly, while allowing light to pass through to the assembly in other regions. In another use, a mask may be employed if the spot size of a laser used to irradiate the glass rod is larger than the width of the line of the glass rod.

As shown in FIG. 2, in another embodiment of the present invention, a hermetically sealed electronic device 10 may further include spacers or pegs 20 positioned above the photovoltaic cell 12 to help releasing the stress store up during the sealing process and prevent damage of photovoltaic cell during storage and transportation.

The spacer or peg can be foam tape, acrylic based adhesive, non-woven fabric, non-woven cloth, or other soft material that can avoid the surface of an electronic device from scratching.

Damp Heat Test (DH test)

A hermetically sealed photovoltaic cell (Photovoltaic cell size: 6 cm×3.7 cm×0.4 cm placed in a hermetic sealed glass tube with round shaped at the top and bottom) was placed into a damp heat test chamber to see whether the cell can survive under IEC 14646 standard test. It is a typical method for testing the weather resistivity of materials, modules or device.

Aging Condition

Temp: 85° C.

Relative humidity: 85%

Test period: 1000 hours

This test condition follows IEC 14646 standard. The result shows that the hermetically sealed photovoltaic cell according to the present invention functions well after the DH test.

According to the present invention, encapsulants, adhesives, or edge sealants for the formation of a hermetic seal between a glass substrate and a substrate to form a hermetically sealed electronic device are no longer necessary. Therefore, the time traditionally to conduct a lamination and an oven curing process of the sealing process can be saved. Meanwhile, both mechanical strength and weather resistivity of the hermetically sealed electronic device can still be maintained.

Since the hermetic condition of the hermetically sealed electronic device can be ensured by the present invention, the present invention can protect the electronic devices by preventing oxygen and moisture in the ambient environment from entering into the assembly.

Moreover, a force applied to at least one of the substrates during the sealing process in order to ensure sufficient contact between the frit and the substrate may not be necessary since the glass rod can provide sufficient contact with the substrates by being positioned against the edges of the substrates.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method of sealing an electronic device, comprising:
providing an assembly comprising first and second substrates in an opposed relationship, and an electronic device positioned between the first and second substrates;
positioning a glass rod against and on the edge of the first and/or second substrate; and
heating and softening the glass rod to form a hermetic seal between the first and second substrates and form a hermetically sealed electronic device.

2. The method of claim 1, wherein the electronic device is a photovoltaic cell, a photovoltaic module or a liquid crystal display.

3. The method of claim 1, wherein the step of heating and softening the glass rod is performed by an irradiation source, a broadband source, or an ultrasonic device.

4. The method of claim 3, wherein the irradiation source is a laser.

5. The method of claim 3, wherein the broadband source is an infrared lamp.

6. The method of claim 1, wherein the step of heating and softening the glass rod is performed by heating the first and/or second substrate.

7. The method of claim 1, wherein the hermetically sealed electronic device has a curved edge.

8. The method of claim 1, wherein the assembly further comprises at least one spacer positioned above the electronic device.

9. The method of claim 8, wherein the spacer is foam tape, acrylic based adhesive, non-woven fabric, or non-woven cloth.

10. A hermetically sealed electronic device made from the method of claim 1.

11. A method of sealing an electronic device, comprising:
providing an assembly comprising first and second substrates in an opposed relationship, and an electronic device positioned between the first and second substrates; and
heating and softening a glass rod and positioning the glass rod against and on the edge of the first and/or second substrate to form a hermetic seal between the first and second substrates and form a hermetically sealed electronic device.

12. The method of claim 11, wherein the electronic device is a photovoltaic cell, a photovoltaic module, or a liquid crystal display.

13. The method of claim 11, wherein the step of heating and softening the glass rod is performed by an irradiation source, a broadband source, or an ultrasonic device.

14. The method of claim 13, wherein the irradiation source is a laser.

15. The method of claim 13, wherein the broadband source is an infrared lamp.

16. The method of claim 11, wherein the step of heating and softening the glass rod is performed by heating the first and/or second substrate.

17. The method of claim 11, wherein the hermetically sealed electronic device has a curved edge.

18. The method of claim 11, wherein the assembly further comprises at least one spacer positioned above the electronic device.

19. The method of claim 18, wherein the spacer is foam tape, non-woven fabric, or non-woven cloth.
